(19) United States
(12) Patent Application Publication
(10) Pub. No.: US 2012/0021916 A1
(43) Pub. Date: Jan. 26, 2012

(54) METHOD AND APPARATUS FOR HEATING SHEET MATERIAL

(75) Inventors: Carsten Buehrer, Bonn (DE); Christoph Fuelbier, Lohmar (DE); Jens Krause, Bonn (DE)

(73) Assignee: ZENERGY POWER GMBH, Rheinbach (DE)

(21) Appl. No.: 13/113,251

(22) Filed: May 23, 2011

(30) Foreign Application Priority Data
Jul. 22, 2010 (DE) 102010031908.2

(51) Int. Cl. F16C 39/06; H05B 6/10; H01L 39/24

(52) U.S. Cl. 505/166; 505/325; 219/646; 219/645; 219/618

(57) ABSTRACT

A method and an apparatus for heating a sheet material made of an electrically conductive, non-magnetic material, the apparatus including at least one coil arrangement with DC-carrying windings that is made to rotate around an axis oriented perpendicular to the sheet material and to thereby induce eddy currents in the sheet material.

### CROSS REFERENCE TO RELATED APPLICATIONS

This application claims foreign priority under 35 U.S.C. §119(a)-(d) to Application No. DE 102010031908.2 filed on 22 Jul. 2010, entitled “A Method and Apparatus for Heating a Flat Material,” the entire contents of which are hereby incorporated by reference.

### BACKGROUND

Assemblies operable to heat metal sheets or slabs through induction are generally known. For example, one conventional assembly includes a coil arrangement made of a winding carrying a direct current on a stationary core which is penetrated by a motorized shaft. A hub body with two arms as south poles is disposed at the end of the shaft at a small distance from one of the large areas of the flat material. The north poles are embodied by the ends of a yoke which encloses the winding and is connected in a torsion-proof manner with the hub body. In another conventional assembly, the slab is placed on a conveyor belt and slowly fed through a furnace, which passes the slab between coil arrangements which are mounted above and below the slab and are supplied with alternating current.

Other assemblies may inductively heat a steel tube in the magnetic field of a coil arrangement, which is supplied with an alternating current and which completely encloses the steel tube, or may inductively heat semi-finished goods or workpieces by moving the workpieces in a static or DC magnetic field. For example, a flat material may be conveyed in a translational manner either between pole pieces of a coil arrangement disposed above or beneath the same, or conversely, the coil arrangement is moved in a translational manner relative to the static flat material. In another assembly, a billet made of an electrically conductive, non-magnetic material is rotated within the interior of a coil arrangement with superconducting windings that encloses the billet, with the material being inductively heated by the generated DC magnetic field.

The above-mentioned conventional assemblies suffer from various disadvantages. The inductive heating by means of DC-supplied coil arrangements, i.e., the generation of short-circuit currents by means of a magnetic alternating field, comes with the disadvantage that considerable ohmic losses in the winding of the coil arrangement/arrangements and hysteresis losses and eddy-current losses also originate in the iron of the coil arrangement/arrangements. For example, in the case of a conventional slab width of 150 cm at a length of 500 cm and a thickness of 20 mm for example, a power of approximately 400 kW which is induced in the slab is necessary for heating from room temperature to 480° C. for example within an acceptable time of 8 min for example.

In addition, while inductive heating by translational reversing transport of a slab in a DC magnetic field could decrease the power dissipation in the coil arrangement to the product of the coil resistance and the square of the coil current, it would still be necessary to provide intensive cooling, usually by using water-carrying copper tubes for the winding of the coil arrangements. This is prevented typically by the large effort necessary to implement a sufficiently fast reversing transport of the workpiece, especially in the case of “large” workpieces, such as slabs.

### SUMMARY

The invention is directed toward to a method for heating a flat or sheet material made of an electrically conductive, non-magnetic material (e.g., a slab, a roll band, or a plate) by inducing eddy currents into the flat material utilizing a coil arrangement including windings carrying a direct current, wherein the coil arrangement is rotatably driven around a rotation axis (e.g., a generally vertical (Z) axis) oriented generally perpendicularly to the surface of the sheet in order to generate a magnetic field that penetrates the sheet at least in part. The flat material, moreover, may be secured to prevent its rotation with respect to the rotation axis (Z-axis).

The invention further relates to an apparatus suitable for performing the above-described method, which is an apparatus for heating a flat material made of an electrically conductive, non-magnetic material (e.g., a slab, a roll band, or plate). The apparatus includes at least one coil arrangement that induces eddy currents within the flat material. The coil arrangement includes windings carrying a direct current that generate a magnetic field operable to penetrate the flat material at least in part, with the coil arrangement being rotatably driven around a rotation axis (e.g., a generally vertical Z axis) oriented substantially perpendicular to the surface of the flat material. The flat material, furthermore, may be secured against rotation about the Z-axis. The coil arrangement further includes a coil support plate capable of operating as a magnetic return path.

In operation, opposing magnetic fluxes that penetrate the flat material are generated by at least two coils arranged symmetrically in relation to the Z-axis, with the support plate for the coils is being used as a magnetic return path. In addition, it is possible to produce relative movement between the flat material and the magnetic field.

### BRIEF DESCRIPTION OF THE DRAWINGS

FIG. 1 illustrates a schematic diagram of a heating apparatus in accordance with an embodiment of the invention.

FIG. 2 illustrates a perspective view of an apparatus having only one coil arrangement.

FIG. 3 illustrates a cross section view of the coil arrangement shown in FIG. 2.

FIG. 4 illustrates a close-up view of the coil arrangement shown in FIG. 3.

FIG. 5 illustrates the apparatus including further including auxiliary units.

Like reference numerals have been used to identify like elements throughout this disclosure.

### DETAILED DESCRIPTION

The method and apparatus according to the invention are especially suitable for flat or sheet material (also called a slab) formed of aluminum, aluminum alloys, copper, and/or copper alloys which need to be heated to a predetermined temperature for further processing, e.g., rolling.

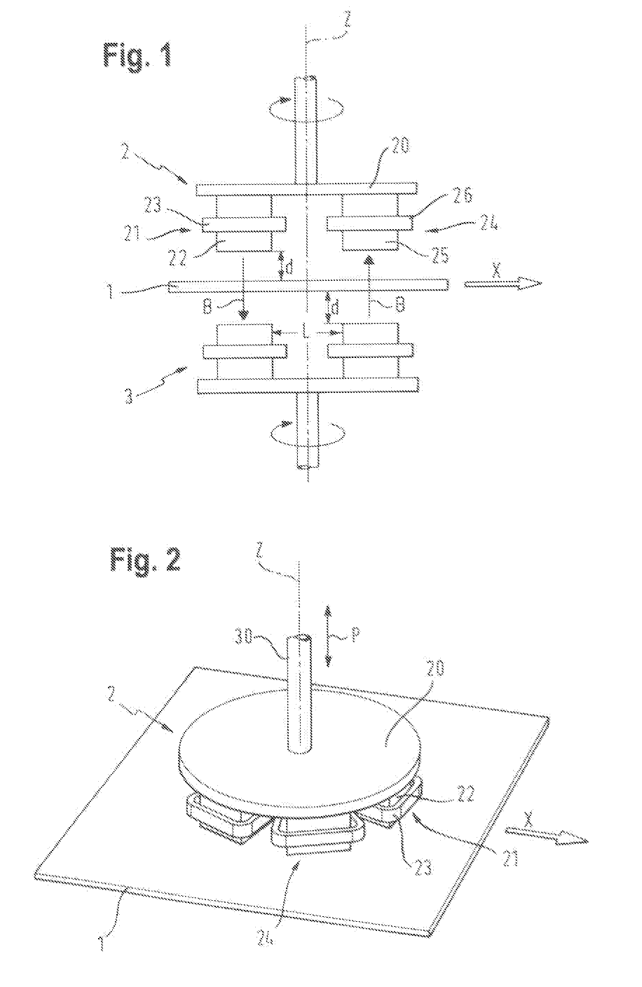

Referring to FIG. 1, a sheet or slab 1 is disposed between a first coil arrangement 2 and a second coil arrangement 3. Both coil arrangements 2, 3 are rotatably driven about a rotational axis Z which is substantially perpendicular to the large areas (the upper/lower sides or surfaces) of the slab 1 (the Z-axis is a vertical axis in FIG. 1). The first coil arrangement 2 (oriented above the slab 1 in FIG. 1) includes a ferromagnetic support plate 20 on which a first coil 21 and a second coil 24 are disposed, being oriented symmetrically (e.g., at radially symmetric positions) about the rotational axis Z (e.g., oriented such that the first coil is diametrically opposed from the second coil). Each of the first coil 21 and the second coil 24 includes a ferromagnetic core 22 and 25, respectively, with a pole face that faces the slab 1, as well as a superconducting winding 23 and 26, respectively. The second coil arrangement 3 (oriented below the slab 1 in FIG. 1) is arranged similarly, including components similar to those of the first coil arrangement 2.

The ferromagnetic cores 22, 25 of the adjacent coils 21 and 24 on the support plate 20 of the first coil arrangement 2 and the ferromagnetic cores of the coils on the support plate of the second coil arrangement 3, which are disposed opposite its corresponding coil on the first coil arrangement 2 and oriented on the opposite side of the slab 1, are magnetized in opposite directions. This leads to opposing magnetic fluxes (indicated by arrows B) that penetrate the slab 1. The distance L between the pole faces of the coil cores (e.g., between opposed cores 22, 25) should be at least approximately three times the air gap d between the terminal pole faces (the surface of the core 22, 25 facing the slab) and the slab 1 in order to keep the share of the field as small as possible, which closes directly from pole face to pole face without penetrating the slab 1 (the air gaps d are exaggerated in the drawings for clarity).

The slab 1 can be stationary, or can move slowly in the plane of its large areas, in the direction X (e.g., transversely along a plane generally orthogonal to the rotational axis of the coil arrangements). The slab 1 may be secured against rotation (e.g., about the Z-axis) caused by the magnetic interaction with the rotating coil arrangements 2, 3. By way of example, its movement with respect to rotational axis Z of the coil arrangement 2, 3 is prevented by holding apparatuses on the outside (lateral) edges of the slab 1 (not illustrated).

The use of two coil arrangements 2, 3 symmetrically disposed on either sides of the slab 1 lead not only to very high magnetic fluxes B through the slab 1, but also to considerably higher eddy currents induced in the slab 1 upon rotation of the coil arrangements about the axis Z, as compared with only one coil arrangement driven with the same speed. The effort invested in a second coil arrangement (e.g., coil arrangement 3), however, may not always compensate for the achieved reduction in the heat-up time of the slab 1. Consequently, it may be desirable to omit the second coil arrangement 3 as illustrated in the embodiment shown in FIG. 2.

Specifically, it may be more economical to provide an apparatus in the embodiment according to FIG. 2, which includes a single coil arrangement 2 oriented proximate the slab 1 (above the slab as shown in FIG. 2). In other words, the second coil arrangement 3 shown in FIG. 1 can be omitted or, preferably, replaced by a ferromagnetic return-path plate spaced by a small air gap d from the bottom large area (the lower side) of the slab 2. In the embodiment illustrated, six coils 21, each including a ferromagnetic cores 22 and windings 23, are arranged on the support plate 20 and positioned proximate the outside circumference (i.e., near the perimetral edge) of the support plate 20. The number of the coils 21 within a coil arrangement 2 is typically based on the dimensions (e.g., the diameter) of the support plate 20. The dimensions (e.g., the diameter) of the support plate 20, in turn, can be selected to accommodate the width of the slab 1. In the case of a large diameter, a further set of coils can be arranged on the remaining area of the support plate. For the purpose of adjustment to different thicknesses of the slab 1, the coil arrangement 2 can be displaceable along the rotational axis (i.e., the Z axis). That is, the coil arrangement 2 may be configured to move toward (downward in FIG. 2) and away from (upward in FIG. 2) the surface of the slab 1 (indicated by double arrow P), in addition to its being rotatable about its rotational axis (the generally vertical, Z axis).

In order to prevent the penetration depth of the magnetic field into the slab 1 from becoming too small as a result of the skin effect, the speed of the coil arrangement 2 should not be substantially higher than about 500 to about 800 rpm (e.g., less than about 800 rpm). The upper speed threshold may depend on not only the type of material forming the slab 1, as well as the slab thickness. The windings 23 are supplied individually or jointly via feed lines, which may be guided through a drive shaft of the coil arrangement 2 arranged in the form of a hollow shaft 30 and end in slip rings.

Acceptable heat-up times require a magnetic flux density of at least 0.1 T and preferably more than 0.5 T in the slab 1 at a speed of the coil arrangement 2 of a few hundred revolutions per minute. Since the high number of ampere turns which are necessary for achieving this flux density can only be achieved by high currents due to the limited winding space, a very high amount of dissipated heat is produced in each coil in normally conducting windings. This heat needs to be dissipated by cooling via a coolant such as a cooling fluid (e.g., water).

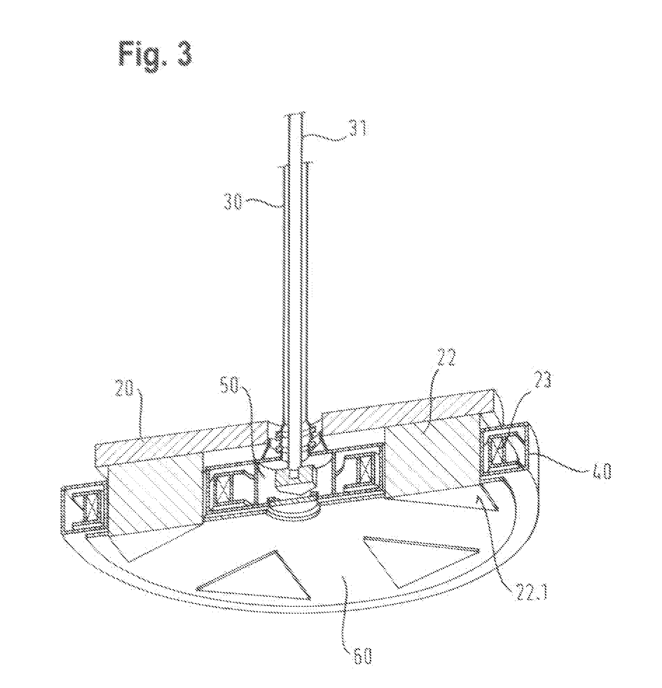

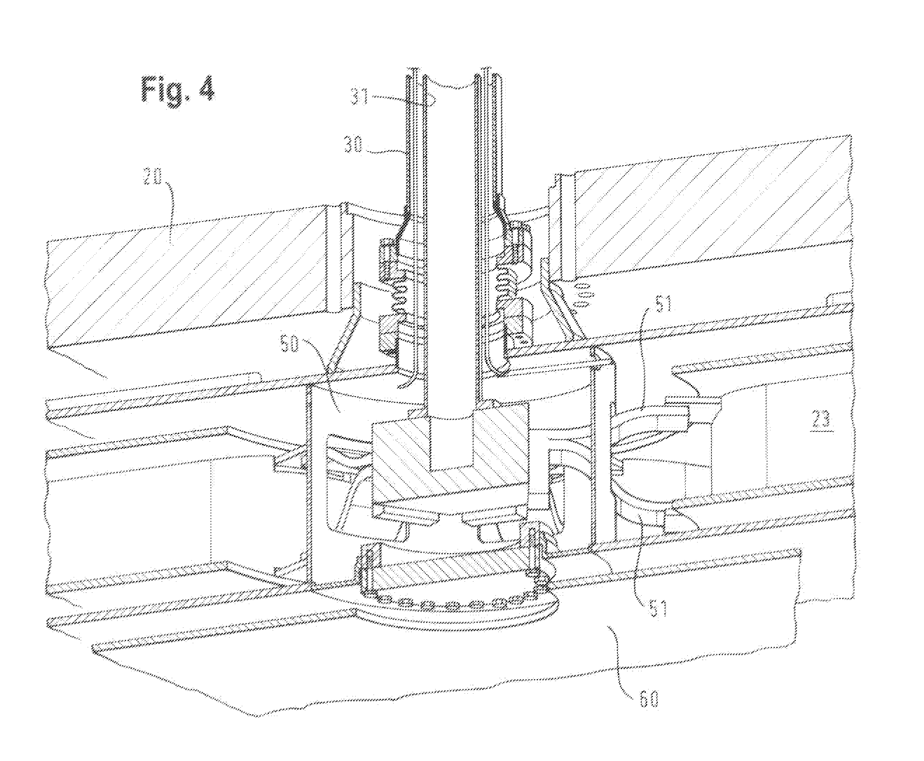

By way of example, the windings 23 may be configured as superconducting windings. Cross sectional views of coil arrangements are shown in FIGS. 3 and 4. In the embodiments illustrated, the support plate 20 is connected in a torsion-proof manner with the hollow shaft 30. The coil cores 22 are fastened to the support plate 20. Each coil core 22 has a winding 23 made of a superconducting (e.g., high-temperature superconducting) and strip-like conductor. The coils are enclosed by a common cryostat 40 including a plurality of recesses (so-called warm bores) for the coil cores 22 so that no cooling power needs to be applied to them. Each winding is cooled by way of a so-called thermal bus 51, which includes, e.g., a massive copper strip connected to a central evaporation unit 50. The evaporation unit 50 is supplied with a fluid cooling agent such as neon or nitrogen via a cooling agent tube 31 that is enclosed concentrically by the hollow shaft 30 from an external stationary refrigerating machine (i.e., a refrigeration unit) via conventional rotary connections. The evaporated cooling agent is returned via the annular space between the hollow shaft 30 and the cooling agent tube 31. The current conductors to the windings 23 also extend into this annular space.

The remaining free space on the support plate 20 may be filled with, e.g., casting resin. The coil cores 22 are accommodated in an interlocking manner in a common reinforcing plate 60 at their ends facing away from the support plate 20, i.e., in the region of their pole faces 22.1 facing the slab 1. The reinforcing plate 60 is made of a non-magnetic, non-conductive material and is used for absorbing the considerable centrifugal and magnetic forces which act on the coil cores 22.

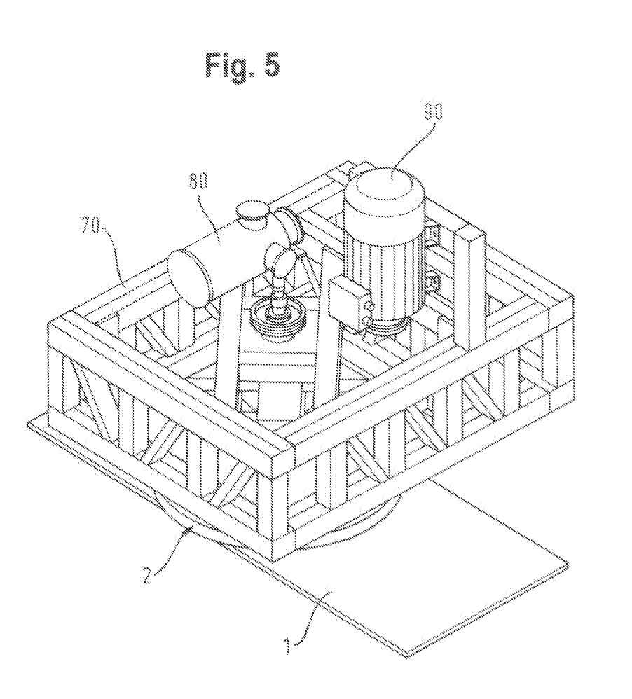

The embodiment illustrated in FIG. 5 shows the slab 1 with the coil arrangement 2 arranged above the slab and whose hollow shaft 30 is held in a massive machine frame 70 to stabilize it against considerable powers of recoil that occur during operation. The machine frame 70 can be arranged above the slab 1 (like a bridge on foundations and supports), with the slab resting on a conventional horizontal conveyor or a fixed foundation (not illustrated in FIG. 5) and secured against twisting as described above. The machine frame 70 also carries the external cooling unit 80 and the electric motor 90, which drives the hollow shaft 30 and thus the coil arrangement 2 (via a transmission).

While the present invention has been described in detail and with reference to specific embodiments thereof, it will be apparent to one skilled in the art that various changes and modifications can be made therein without departing from the spirit and scope thereof.

Preferably, the magnetic field is generated by means of superconducting windings of the coil arrangement. By way of example, conventional superconducting wires and strips may be utilized. The considerable power losses in a coil arrangement with a normally conductive winding (which are incurred in the form of exhaust heat) are prevented in this manner. By way of example, in the case of an installation with a connected load of 500 kW (the sum total of electrically generated mechanical drive power for the rotary drive and electric power for generating the magnetic field), the saved electric power by using a coil arrangement with superconducting windings is approximately 250 kW. Especially preferred are windings made of a high-temperature superconducting material, because in this case the coil arrangement can be cooled with liquid neon or even liquid nitrogen instead of liquid helium, so that the power requirements for the cooling are respectively lower.

In the case of a coil arrangement with superconducting windings, cooling preferably occurs via a hollow shaft by means of one of the mentioned cooling fluids which is guided in a circuit between a stationary cooling unit and the coil arrangement. Additional energy savings are achieved when only the windings of the coil arrangement are cooled. The windings are best connected for this purpose via metal bridges of high thermal conductivity with the cold side of a heat exchanger which is mounted in the center of the coil arrangement.

An apparatus of the kind mentioned above which is suitable for performing the method is characterized in that the coil arrangement comprises a support plate on which at least two (preferably three or more) coils are disposed symmetrically in relation to the Z-axis (e.g., arranged at predetermined radial locations from the rotation axis, arranged at radially symmetric positions about the rotation axis, located at diametrically opposed locations, or arranged equidistantly from the rotation axis at predetermined locations), of which each comprises one ferromagnetic core with a pole face facing the flat material and a winding, with the support plate is arranged as a magnetic return path for the poles of the coils facing away from the flat material.

The flat material and the magnetic field can be arranged to be movable with respect to one another.

Preferably, the poles of adjacent coils are magnetized in opposite directions to increase the induction in the flat material. This can be achieved in such a way that the windings of adjacent coils are operated with opposite current flow directions. This can occur either by supplying the windings in opposite directions or by providing oppositely disposed windings with supply of the windings in the same direction.

In order to ensure that a large part of the magnetic flux penetrates the flat material, the distance between the pole faces of the coils should at least be three times the air gap between these pole faces and the flat material.

The support plate on which the coils are disposed is preferably arranged as a magnetic return path for the poles of the coil facing away from the flat material.

The shape and dimensions are not particularly limited. By way of example, support plate 20 may be in the form of a generally circular disk.

In order to further increase the induction in the flat material, a magnetic return-path plate can be arranged on the (bottom) large area of the flat material facing away from the coil arrangement, spaced from the latter by an air gap.

An even higher induction is achieved if a second substantially similar rotating coil arrangement is disposed on the large area of the flat material which faces away from the coil arrangement, and is also spaced from the same by an air gap.

The windings of the coil arrangement are superconducting for the reasons as explained above, preferably high-temperature conducting.

The rotational axis of the support plate is preferably defined by a hollow shaft which coaxially encloses a feed and return line for a cooling fluid, at least two conductors for supplying the coil windings, and a tube which delimits a cold-insulating evacuated annular space, with a static refrigerating machine being arranged at the end of the hollow shaft facing away from the support plate, which refrigerating machine provides the cooling fluid in a cyclic process.

The electric motor 90 is preferably arranged in an equiaxed manner in relation to the shaft or hollow shaft driving the support plate and parallel offset in relation to them, which electric motor is in a drive connection with the shaft or hollow shaft. As a result of the high efficiency of electric motors, especially rotary current motors or rotary field motors, the heat power introduced into the flat material is nearly equivalent to the electric power with which the electric motor is driven. This electric power can easily be controlled by way of a frequency converter which determines the speed of the electric motor.

Considerable centrifugal and magnetic forces act on the coil cores. The coil cores can be connected by at least one non-magnetic reinforcing plate for mechanical securing.

The winding of the coils are enclosed by a common cryostat if they are superconducting, which cryostat has a non-cooled passage for each coil core. A considerable amount of refrigerating power is saved in comparison with cooling for each coil and even more in comparison for cooling the entire coil arrangement.

The coil arrangement can comprise a central evaporation unit for cooling which is arranged as a heat exchanger (a so-called cold head), with which each winding is connected via a metal bridge of high thermal conductivity.

The coil arrangement and the flat material such as the slab can be displaceable in a translational way in at least one direction relative to one another. As a result of a translational displacement in the longitudinal direction of the slab, it can be brought to the desired temperature evenly over its entire length. If the width of the slab is larger than the diameter of the rotating coil arrangement, an even heating can also be achieved over the entire width as a result of a translational displacement transversely to the slab.

Preferably, the flat material rests on a linear conveyor, e.g., a roller table which is made of non-magnetic materials at least in the region of the rotating coil arrangement.

Although the disclosed inventions are illustrated and described herein as embodied in one or more specific examples, it is nevertheless not intended to be limited to the details shown, since various modifications and structural changes may be made therein without departing from the scope of the inventions and within the scope and range of equivalents of the claims. In addition, various features from one of the embodiments may be incorporated into another of the embodiments. Accordingly, it is appropriate that the appended claims be construed broadly and in a manner consistent with the scope of the disclosure as set forth in the following claims.

It is to be understood that terms such as “left,” “right,” “top,” “bottom,” “front,” “rear,” “side,” “height,” “length,” “width,” “upper,” “lower,” “interior,” “exterior,” “inner,” “outer” and the like as may be used herein, merely describe points or portions of reference and do not limit the present invention to any particular orientation or configuration. Further, terms such as “first,” “second,” “third,” etc., merely identify one of a number of portions, components and/or points of reference as disclosed herein, and do not limit the present invention to any particular configuration or orientation.

What is claimed is:

1. A method for heating a slab made of an electrically conductive, non-magnetic material, the method comprising:
(a) inducing eddy currents into the slab by means of at least one coil arrangement with windings carrying a direct current, the coil arrangement being rotatably driven around a rotation axis oriented substantially perpendicular to a surface of the slab in order to generate a magnetic field that at least partially penetrates the slab;
(b) securing the slab against rotation about the rotation axis; and
(c) generating opposing magnetic fluxes that penetrate the slab via at least two coils arranged symmetrically in relation to the rotation axis, for which a support plate for the coils is used as a magnetic return path.

2. The method according to claim 1, wherein relative movement is produced between the slab and the magnetic field.

3. The method according to claim 1, wherein:
the windings comprise superconducting windings; and
the magnetic field is produced via the superconducting windings of the coil arrangement.

4. The method according to claim 3 further comprising (d) cooling the coil arrangement with a coolant, wherein the coolant is circulated between a refrigeration unit and the coil arrangement via a hollow shaft.

5. The method according to claim 4, wherein only the windings of the coil arrangement are cooled.

6. The method according to claim 5, wherein the windings of the coil arrangement are connected for cooling purposes via metal bridges of high thermal conductivity with the cold side of a heat exchanger mounted centrally within each coil arrangement.

7. A heating apparatus for heating a sheet formed of an electrically conductive, non-magnetic material by inducing eddy currents within the sheet, the apparatus comprising a coil arrangement including:
windings carrying a direct current operable to generate a magnetic field that at least partially penetrates the sheet, wherein the coil arrangement is rotatably driven around a rotation axis oriented substantially perpendicular to a surface of the sheet; and
a support plate, at least two coils disposed on the support plate and oriented symmetrically about the support plate in relation to the coil arrangement rotational axis, wherein each coil comprises a ferromagnetic core having a pole face facing the sheet and a winding, and wherein the support plate is a magnetic return path for the poles of the coils facing away from the sheet,
wherein the sheet is secured against rotation about the coil arrangement rotation axis.

8. The apparatus according to claim 7, wherein the sheet and the magnetic field are movable relative to one another.

9. The apparatus according to claim 7, wherein the windings of adjacent coils disposed on the support plate have opposing directions of current flow.

10. The apparatus according to claim 7, wherein the distance between the adjacent coils disposed on the support plate measures at least three times the distance of an air gap between pole faces facing the sheet and a surface of the sheet.

11. The apparatus according to claim 7, wherein a magnetic return path plate is arranged proximate a surface of the sheet disposed opposite the coil arrangement, the plate being spaced from the sheet surface by an air gap.

12. The apparatus according to claim 7, wherein:
the coil arrangement comprises a first coil arrangement disposed proximate a first surface of the sheet and being spaced from the sheet first surface by a first air gap; and
the apparatus further includes a second rotating second coil arrangement disposed proximate a second surface of the sheet opposite the first sheet surface, the second coil arrangement being spaced from the sheet second surface by a second air gap.

13. The apparatus according to claims 7 further comprising:
a hollow shaft disposed along the coil arrangement rotational axis, wherein the hollow shaft encloses a feed and return line for a cooling fluid;
at least two conductors to feed the coil windings;
a tube which delimits an evacuated annular space; and
a static refrigeration unit operable to circulate the cooling fluid within the feed and return line.

14. The apparatus according to claim 13 further comprising an electric motor operable to drive the hollow shaft is configured to rotate the coil arrangement.

15. The apparatus according to claim 7, wherein the ferromagnetic cores of the coils are connected via a non-magnetic reinforcing plate.

16. The apparatus according to claim 7, wherein the windings of the coil arrangement are superconducting windings.

17. The apparatus according to claim 16, wherein the superconducting windings are enclosed within a cryostat including a non-cooled passage for each coil core.

18. The apparatus according to claim 17, wherein the coil arrangement further comprises a central evaporation unit configured as a heat exchanger, with which each winding is connected via a metal bridge of high thermal conductivity.

19. The apparatus according to claim 7, wherein the coil arrangement and the sheet are displaceable in at least one direction relative to one another in a translational motion.

20. The apparatus according to claim 7, further comprising a linear conveyor for the sheet material.

21. A method comprising:
(a) positioning a sheet formed of electrically conductive, non-magnetic material proximate a coil arrangement, the coil arrange being rotatable about a rotation axis, wherein:
the sheet comprises a first surface and an opposed second surface, and
the coil arrangement includes a support plate and a pair of coils including windings, the coil forming the pair being disposed at radially symmetric positions about the rotation axis of the coil arrangement, the support plate operating as a magnetic return path; and
(b) generating opposing magnetic fluxes operable to penetrate the sheet to induce eddy currents within the sheet,
wherein the rotation axis of the coil arrangement is oriented substantially perpendicular to the first surface of the sheet material.

22. An apparatus for inductively heating a sheet formed of electrically conductive, non-magnetic material, the sheet having a first sheet side facing the apparatus and a second sheet side opposite the first sheet side, the apparatus including:
a support plate having a first plate surface and a second plate surface, wherein the support plate is configured to rotate about a rotation axis;
a plurality of coils disposed on the second plate surface, wherein the plurality of coils includes a first coil is diametrically opposed from a second coil, the first and second coils being separated by a predetermined coil distance, wherein each coil comprises:
a ferromagnetic core having a first pole in contact with the support plate and a second pole facing the first sheet side, the second pole being spaced from the first sheet side by a predetermined air gap distance, and
a superconducting winding surrounding the ferromagnetic core,
wherein the support plate is a magnetic return path for first pole in contact with the support plate, the coil distance is at least three times the air gap distance, and the first coil and the second coil are magnetized in opposite directions.
